(19) United States
(12) Patent Application Publication
(10) Pub. No.: US 2010/0117985 A1
(43) Pub. Date: May 13, 2010

(54) CAPACITIVE TOUCH SCREEN AND STRATEGIC GEOMETRY ISOLATION PATTERNING METHOD FOR MAKING TOUCH SCREENS

(76) Inventor: Bahar Wadia, Bartlett, IL (US)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(21) Appl. No.: 12/614,072

(22) Filed: Nov. 6, 2009

Related U.S. Application Data
(60) Provisional application No. 61/112,064, filed on Nov. 6, 2008.

(51) Int. Cl. G06F 3/044; H05K 3/02; B23K 26/36

(52) U.S. Cl. 345/174; 29/847; 219/121.69

(57) ABSTRACT

A new patterning technique, known as Strategic Geometry Isolation (SGI), is used to pattern conductive film structures using laser ablation. In addition to ITO films, SGI may also be used to pattern any other conductive film amenable to ablation with a laser or other directed energy beam. Instead of ablating large areas of ITO to create an ITO void through which underlying layers in a MIPC can project a capacitive field, the SGI patterning technique involves leaving in place, but electrically isolating, the areas that would have been ablated. The electrical isolation of these areas may be accomplished with a single pass of the ablation path. In use, the electrically isolated areas behave similarly to the ITO voids/ablated areas, allowing the underlying capacitive field to project through them. The coupling provided by the electrically isolated areas for the combined layers enhances the capacitive field of the underlying layers.

### RELATED APPLICATIONS

This application claims the benefit of U.S. Provisional Patent Application No. 61/112,064, entitled CAPACITIVE TOUCH SCREEN AND PATTERNING METHOD FOR MAKING TOUCH SCREENS, filed Nov. 6, 2008, hereby fully incorporated herein by reference.

### FIELD OF THE INVENTION

The present invention relates generally to capacitive touch screens, and more specifically, methods for making capacitive touch screens.

### BACKGROUND OF THE INVENTION

Touch screens are displays that can sense the position of the touch of a finger or other passive object, such as a stylus. They are commonplace and used in applications ranging from cash registers to automatic teller machines to hand-held devices. A number of technologies are used for touch screens, including resistive touch screen panels, surface acoustic wave technology, strain gauge configurations, optical imaging, dispersive signal technology, acoustic pulse recognition, and capacitive touch screen panels.

Capacitive touch screens are used in many applications, including the Apple® iPhone. Panels of capacitive touch screens are typically coated with a material that stores electrical charge, thus being capable of conducting a continuous electrical current across a sensor. One common structure used for capacitive touch screens is a plastic film coated with a conductive material such as indium tin oxide (ITO). The sensor exhibits a precisely controlled field of stored charge in both the horizontal and vertical axes, achieving electrical capacitance. Because the human body is also technically an electrical device with stored charge, it too exhibits capacitance. Thus, when the panel is touched, a small amount of charge is drawn to the point of contact on panel, causing the charge on the capacitive layer to decrease. The panel also comprises circuits located at the corners that measure the charge on the capacitive layer. Relative changes in charge may be measured, and the information may then be sent to a controller for processing to determine the precise location of the touch.

ITO-coated polyethylene terephthalate (PET) or polyethylene naphthalate (PEN) films, commonly called ITO films, are widely used in the manufacturing of capacitive touch screens. These films are also used in the manufacturing of electronic components ranging from simple electric heaters to highly complex flat screen color displays. ITO is electrically conductive, and PET or PET is dielectric. Similar to a typical printed circuit board consisting of a copper conductor and a fiberglass dielectric as a carrier, the ITO acts as a conductor, and the PET or PEN film acts as the carrier and insulator for the ITO. Unlike copper, however, ITO is transparent, making it ideal for use in applications like touch screens.

ITO films are often produced in continuous roll format and cut to size to meet end-application requirements. Similar to a printed circuit board, occasionally these films require added processing during which a pattern is etched onto the film by removing the ITO coating. This process allows the creation of electrical circuits similar to a printed circuit board. Several different processes are used in industry to etch ITO from the film. One of these processes is laser ablation.

Laser ablation is a process by which ITO from an ITO film is removed by bombarding a laser beam onto the ITO film. As depicted generally in prior art FIG. 1, ITO is removed from an ITO film by bombarding a laser beam onto the ITO film. The ITO on the ITO film absorbs the laser energy, ablating itself, wherever the laser beam contacts the ITO. This effectively allows the creation of patterns on the ITO such that areas on the film that have ITO are electrically conductive and those that do not have ITO are dielectric. This effectively enables the creation of the basic building blocks of an electrical circuit, where ITO areas are conductive and ablated areas are dielectric. Usually a pulsed laser is used during laser ablation, although a continuous wave laser beam may also be used if the intensity of the laser is high enough.

As depicted in prior art FIG. 2, laser ablation may be used to remove large areas of ITO to create a large ITO ablated region. This technique, however, is time-consuming, inefficient, and expensive because multiple adjacent passes of the laser are necessary to ablate the entire area. For example, if the laser beam width is 30 μm, then 333 adjacent passes would be needed to ablate a region with a width of 10 mm.

The nature and physics of laser beams used in the ablation process limits the ablation path (the width of the laser beam) typically to no greater than 100 μm. Therefore, to achieve a pattern that requires large areas of ITO ablation, for example, an area of 100 mm², multiple adjacent lines must be ablated. This is a very time consuming and inefficient process as the laser is repeatedly guided back and forth to ablate an area larger than the ablation path, one line at a time. This process becomes especially inefficient and economically infeasible when used in the manufacturing of capacitive touch screens, which have patterns on the ITO film that require etching/ablation of large areas of ITO. Consequently, other processes such as chemical etching are usually used for patterns requiring removal of large areas of the ITO. Drawbacks of chemical etching, however, are that it requires the use and handling of toxic and hazardous chemicals, extensive process equipment and facilities, and a large investment of time and effort in process design and set up for each different pattern to be produced. Consequently, it is generally only economically and practically feasible for large production runs of a given pattern. Capacitive touch screens are often made using a multilayer configuration in which several ITO films are stacked together. This type of capacitive touch screen construction is referred to as a multilayer interdigitated projected capacitance touch screen (MIPC). An example of such a prior art MIPC structure is disclosed in U.S. Patent Application Publication No. 2004/0119701 A1, hereby fully incorporated herein by reference. In MIPC structures, individual separate layers of ITO film incorporate patterns that interdigitate when assembled together. The interdigitation enables the underlying layers to project a capacitive field through large ITO voids in the layers above. Because of the large ITO voids previously thought to be needed for them to function, and because of the drawbacks described above for using laser ablation over large areas, MIPCs have typically been made using chemical etching processes rather than laser ablation. This has resulted in MIPCs being used only for large volume products where chemical processes can be used efficiently and economically.

MIPC touch screens are typically formed from a plurality of individual layers of patterned ITO or other conductive film as depicted in prior art FIGS. 3a, 3b, and 4. Individual layer structures 20, 22, are formed from ITO film or other similar conductive film material. A first pattern 24 of electrically connected pads 26 is formed on the surface of layer structure 20 by removing the ITO in all regions except in the pattern 24 areas. In the ablated region 28, the underlying polymer material 29, generally PET or PEN is exposed. Similarly, second pattern 30 of electrically connected pads 32 is formed on the surface of layer structure 22 by removing the ITO in all regions except in the pattern 30 areas. Again, in the ablated region 34, the underlying polymer material 35, generally PET or PEN, is exposed. Generally, the ablation of ITO material in these prior art structures is performed by chemical methods using a mask or other such structure to define patterns 24, 30.

Layer structures 20, 22, are then stacked as depicted in FIGS. 4 and 5 to form MIPC structure 36. Layer structure 22 is positioned under layer structure 20 with pads 32 of pattern 30 registered with ablated regions 28 between pads 26 of overlying patterns 24. A top layer 38 of clear polymer material may then be overlain so as to present a touch surface 40. In use, the capacitance of pads 32 is “projected” upwardly through polymer material 29 of layer structure 20.

In addition to the drawbacks associated with ablating large areas of ITO to form ablated regions 28, 34, there are at least two other drawbacks associated with these prior art methods and structures. First, the underlying pads 32 are located at a greater distance from touch surface 40 than pads 26 and must project through polymer material 29. This results in layer structure 22 having generally less sensitivity than layer structure 20, thereby requiring appropriate compensation in the controller circuitry in order to ensure accuracy. Also, ITO material does not transmit 100% of light incident on it. Consequently, the pattern areas 24, 30, will transmit less light through than the ablated areas 28, 34. When the layer structures 20, 22, are stacked, the bridge areas 42 electrically connecting pads 26 in pattern 24 and the bridge areas 44 electrically connecting pads 30 in pattern 32 overlie at points 46 in the completed MIPC structure 36. If the ITO material of patterns 24, 30, is sufficiently thick, these points 46 may be visible to the naked eye, presenting an undesirable pattern of dots on the completed touch screen. Consequently, the ITO material is generally made as thin enough to avoid this effect in prior art MIPC touch screens. But, resistance of the patterns 24, 30, is increased as the ITO layer is made thinner, thereby reducing sensitivity.

There exists a need in the industry for a method of making MIPC and other capacitive touch screens that overcomes the drawbacks of prior art methods.

### SUMMARY OF THE INVENTION

Embodiments of the present invention address the need of the industry and overcome the drawbacks of prior art methods for producing capacitive touch screens, and in particular, MIPCs. According to embodiments, a new patterning technique, hereafter known as Strategic Geometry Isolation (SGI), is used to pattern conductive film structures using laser ablation. In addition to ITO films, SGI may also be used to pattern any other conductive film amenable to ablation with a laser or other directed energy beam.

According to embodiments of the invention, instead of ablating large areas of ITO to create an ITO void through which underlying layers in a MIPC can project a capacitive field, the SGI patterning technique involves leaving in place, but electrically isolating, the areas that would have been ablated. The electrical isolation of these areas may be accomplished with a single pass of the ablation path. In use, the electrically isolated areas behave similarly to the ITO voids/ablated areas, allowing the underlying capacitive field to project through them. Furthermore, the coupling provided by the electrically isolated areas for the combined layers actually enhances the capacitive field of the underlying layers. This significantly improves the performance of MIPCs.

Accordingly, in an embodiment, a multilayer interdigitated projected capacitance touch screen includes a substantially transparent first layer comprising a dielectric film presenting a pair of opposing surfaces, wherein at least one of the opposing surfaces of the film is coated with a conductive material, the conductive material defining a plurality of electrically interconnected regions and a plurality of electrically isolated regions adjacent and interspersed with the electrically interconnected regions, and a substantially transparent second layer comprising a dielectric film presenting a pair of opposing surfaces, wherein at least one of the opposing surfaces of the film is coated with a conductive material, the conductive material defining a plurality of electrically interconnected regions and a plurality of electrically isolated regions adjacent and interspersed with the electrically interconnected regions, the second layer superimposed on the first layer such that each of the electrically interconnected regions of the first layer is overlain with an electrically isolated region of the second layer, and each of the electrically isolated regions of the first layer is overlain with an electrically interconnected region of the second layer.

In embodiments, the conductive material of the first layer and the conductive material of the second layer may be substantially indium tin oxide. The dielectric film of the first layer and the dielectric film of the second layer may be substantially polyethylene terephthalate or polyethylene naphthalate.

In further embodiments, the electrically interconnected regions of a layer may be separated from the electrically isolated regions of the same layer by 100 μm or less. In other embodiments, the electrically interconnected regions of the layer may be separated from the electrically isolated regions of the same layer by 30 μm or less. In some embodiments, the electrically isolated regions of the first layer and the electrically isolated regions of the second layer are substantially square in shape.

In further embodiments, a method of making a multilayer interdigitated projected capacitance touch screen includes producing a first substantially transparent screen layer by using a directed energy beam ablation device to define a plurality of electrically interconnected regions and a plurality of electrically isolated regions adjacent and interspersed with the electrically interconnected regions in a conductive material coated on a dielectric material, and producing a second substantially transparent screen layer by using the directed energy beam ablation device to define a plurality of electrically interconnected regions and a plurality of electrically isolated regions adjacent and interspersed with the electrically interconnected regions in a conductive material coated on a dielectric material. The method may further include superimposing the second layer on the first layer such that each of the electrically interconnected regions of the first layer is overlain with an electrically isolated region of the second layer, and each of the electrically isolated regions of the first layer is overlain with an electrically interconnected region of the second layer.

In embodiments of the invention, the directed energy beam ablation device is a laser. In other embodiments, the directed energy beam ablation device may be an electron beam generator or a microwave beam generator.

In some embodiments, the step of defining the plurality of electrically interconnected regions and the plurality of electrically isolated regions in the conductive material of the first layer is accomplished with one continuous pass of the directed energy beam ablation device. In some embodiments, the step of defining the plurality of electrically interconnected regions and the plurality of electrically isolated regions in the conductive material of the second layer is accomplished with one continuous pass of the directed energy beam ablation device.

In other embodiments, a capacitive touch screen includes at least one substantially transparent layer comprising a dielectric film presenting a pair of opposing surfaces, wherein at least one of the opposing surfaces of the film is coated with a conductive material, the conductive material defining a plurality of electrically interconnected regions and a plurality of electrically isolated regions adjacent and interspersed with the electrically interconnected regions. The conductive material may be substantially indium tin oxide. The dielectric film may be substantially polyethylene terephthalate or polyethylene naphthalate. The electrically interconnected regions may separated from the electrically isolated regions by 100 μm or less in some embodiments. The electrically interconnected regions may be separated from the electrically isolated regions by 30 μm or less in other embodiments. In further embodiments, the electrically isolated regions may be substantially square in shape.

### BRIEF DESCRIPTION OF THE DRAWINGS

The invention may be more completely understood in consideration of the following detailed description of various embodiments of the invention in connection with the accompanying drawings, in which:

FIG. 1 depicts a prior art process of laser ablation for etching ITO film;

FIG. 2 depicts the prior art use of laser ablation for etching multiple adjacent lines on ITO film;

FIG. 3a depicts a segment of ITO film etched according to a prior art process to form conductive structures for use in a MIPC touch screen;

FIG. 3b depicts a segment of ITO film etched according to a prior art process to form conductive structures for use in a MIPC touch screen in conjunction with the segment of FIG. 3a;

FIG. 4 depicts the segments of FIGS. 3a and 3b layered together in a MIPC touch screen;

FIG. 5 is a cross-sectional view taken at section 5-5 of FIG. 4;

FIG. 6 is a top plan view of a fragmentary portion of a MIPC touch screen according to an embodiment of the invention;

FIG. 7 is a fragmentary view of an ITO coated film segment showing an ablation path for a Strategic Geometry Isolation method in an intermediate stage of completion;

FIG. 8 is a fragmentary view of the ITO coated film segment of FIG. 7 showing the ablation path at a later intermediate stage of completion;

FIG. 9 is a fragmentary view of the ITO coated film segment of FIG. 7 showing the ablation path at completion;

FIG. 10 is a top plan view of an ITO film segment ablated according to an embodiment of the invention, depicting electrically isolated regions adjacent and interspersed with electrically interconnected regions;

FIG. 11 is a cross-sectional view taken at section 11-11 of FIG. 10;

FIG. 12 is a fragmentary top plan view of a MIPC touch screen structure according to an embodiment of the invention; and

FIG. 13 is a cross-sectional view taken at section 13-13 of FIG. 12.

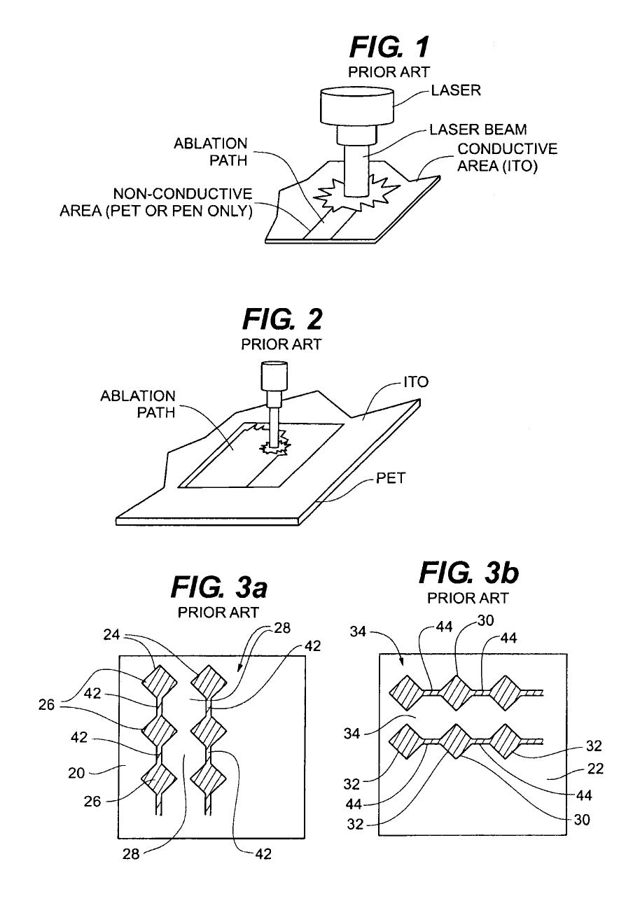

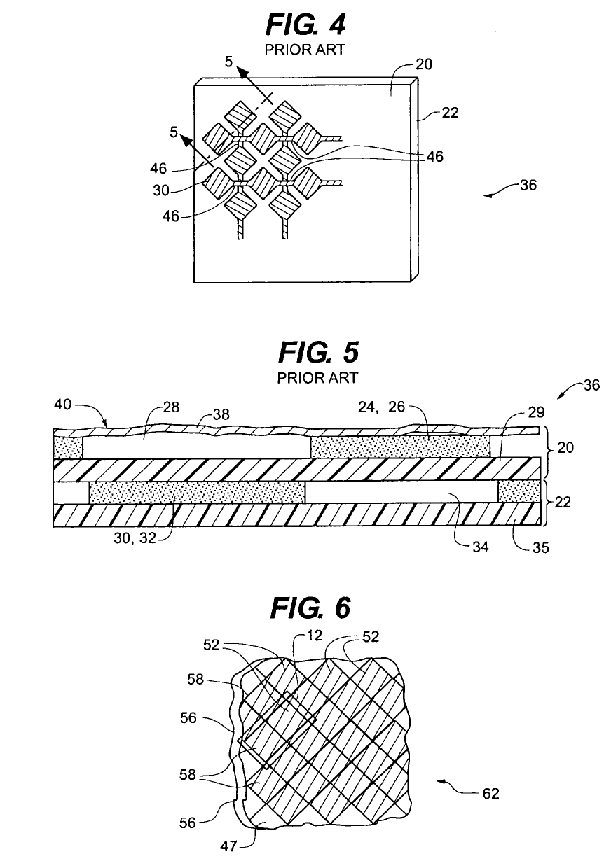

While the present invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

In the following detailed description of the present invention, numerous specific details are set forth in order to provide a thorough understanding of the present invention. However, one skilled in the art will recognize that the present invention may be practiced without these specific details. In other instances, well-known methods, procedures and components have not been described in detail so as to not unnecessarily obscure aspects of the present invention.

The present invention is a directed to a capacitive touch screens and a method for making capacitive touch screens. The technique described herein for manufacturing MIPCs may be known as Strategic Geometry Isolation (SGI). Instead of ablating large areas of ITO, the SGI patterning technique according to embodiments of the present invention involves defining electrically isolated areas on the ITO film.

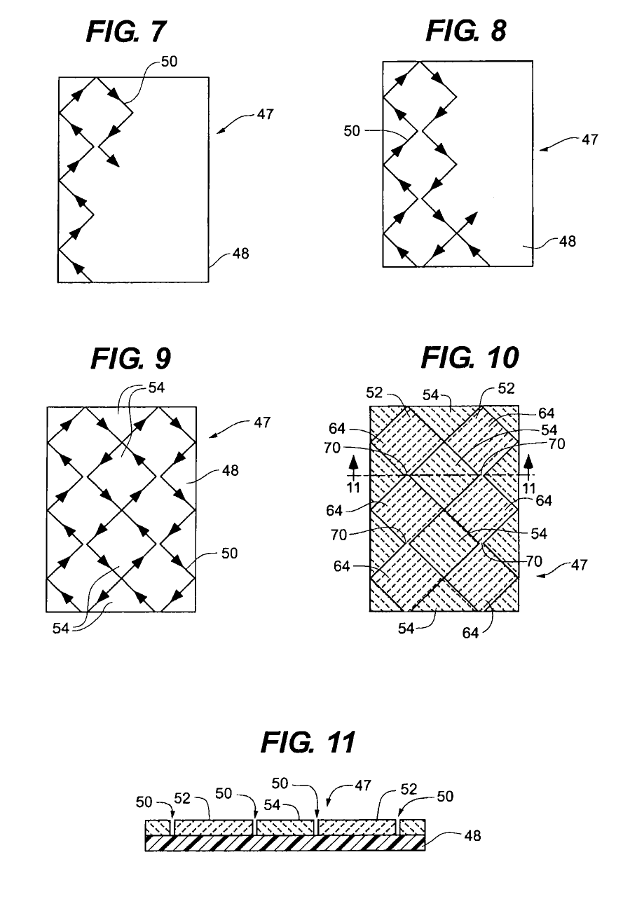

As depicted in FIGS. 7-11, a layer structure 47 is formed from ITO film 48 by ablating a single path in the direction of the arrows using a directed energy beam ablation device, such as a laser, to form adjacent electrically interconnected conductive regions 52 separated by electrically isolated conductive regions 54. Advantegeously, the ablation may be performed in a single pass, and the ablation path generally needs only to be as wide as the energy beam itself. One or more other layer structures 56 may then be formed from ITO film in a similar fashion. Each of these layer structures 56 has adjacent electrically connected conductive regions 58 separated by electrically isolated conductive regions 60. As depicted in FIGS. 6, 12 and 13, layer structure 47 is then overlaid on the layer structure 56 to form MIPC structure 62. Pads 64 of regions 52 are registered over electrically isolated conductive regions 60 of layer structure 56, while pads 66 of regions 58 are registered under electrically isolated conductive regions 54 of layer structure 47.

MIPC structure 62 formed with the SGI patterning technique has a number of important advantages over prior art MIPC structures. One advantage is that, in use, the pads 66 of the underlying layer structure 56 capacitively couple with the overlying electrically isolated conductive regions 54, thereby effectively “extending” the capacitive effect of pads 66 upward to touch surface 68. The sensitivity of layer structures 47 and 56 is thereby much more evenly matched than in prior art MIPC structures, obviating or eliminating completely the need for compensation in the touch screen controller and improving overall sensitivity and performance of the touch screen.

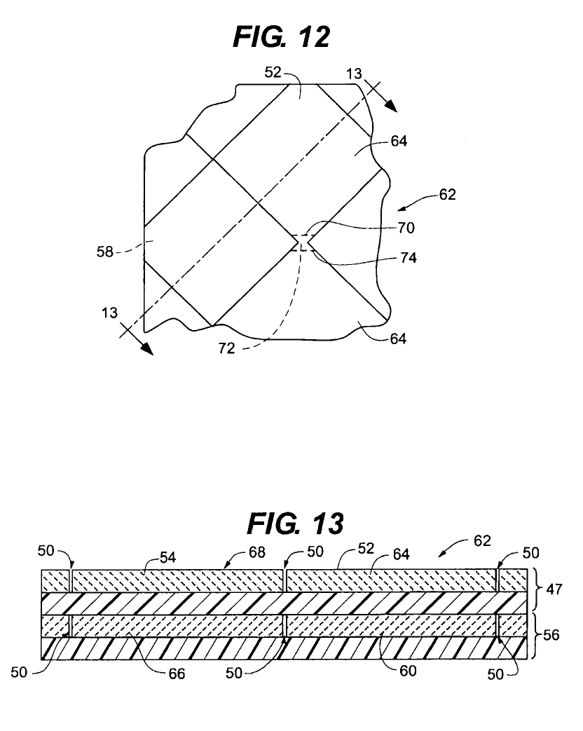

Another advantage of MIPC structure 62 lies in the fact that ITO material is only ablated in a very narrow laser ablation path 50. Path 50 is typically only the width of the laser ablation beam and is typically invisible to the naked eye. Preferably the width of the ablation path is 100 μm or less in some embodiments and may be 30 μm or less in some embodiments. As a result, since there are no ablated regions visible with the naked eye, light transmission is nearly homogeneous through all portions of layer structures 47 and 56. When the layer structures 47, 56, are stacked, the bridge areas 70 electrically connecting pads 64 in regions 52 and the bridge areas 72 electrically connecting pads 66 in regions 58 overlie at points 74 in the completed MIPC structure 62 as depicted in FIG. 12. But, because the light transmission of the layers 47, 56 is homogeneous, points 74 are generally not visible to the naked eye, regardless of the thickness of the ITO in regions 52, 58. Consequently, the ITO material can be thicker than in prior art MIPC touch screens without compromising appearance, and thereby improving touch screen sensitivity and performance.

In addition to these advantages, the SGI patterning method according to embodiments of the invention enables cost effective fabrication of capacitive touch screen components using laser ablation. The single pass ablation of SGI patterning can be performed in a fraction of the time necessary for ablation of large areas as required in prior art methods. In addition, the use of directed energy beam ablation techniques enables the expense and difficulty of other prior art methods such as chemical etching to be avoided.

It will be appreciated by those of ordinary skill in reading this disclosure that numerous variations of the invention may be contemplated and are within the scope of the present invention. For example, in addition to ITO film any other conductive film material may be patterned using the SGI technique, including for example, films having different conductive materials thereon, such as carbon nanotubes. It will be appreciated that any material subject to energy beam ablation may be used. It will also be appreciated that the present invention is not limited to particular geometries or physical structures. For example, any pattern of alternating conductive patterns and electrically isolated conducting areas may be formed with the present method, whether accomplished by ablating a continuous single path or a plurality of continuous paths. Also, although MIPC structures with two layers are depicted herein, any number of layers with interdigitated structures may be combined to form an MIPC structure according to embodiments of the invention. Further, although the embodiment described hereinabove refers to ablation using laser energy, it will be appreciated that other directed energy beams that may be suitable for ablation are encompassed within the scope of the present invention, including for example and without limitation, an electron or microwave beam.

Various modifications to the invention may be apparent to one of skill in the art upon reading this disclosure. For example, persons of ordinary skill in the relevant art will recognize that the various features described for the different embodiments of the invention can be suitably combined, un-combined, and re-combined with other features, alone, or in different combinations, within the spirit of the invention. Likewise, the various features described above should all be regarded as example embodiments, rather than limitations to the scope or spirit of the invention. Therefore, the above is not contemplated to limit the scope of the present invention.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A multilayer interdigitated projected capacitance touch screen comprising:
a substantially transparent first layer comprising a dielectric film presenting a pair of opposing surfaces, wherein at least one of the opposing surfaces of the film is coated with a conductive material, the conductive material defining a plurality of electrically interconnected regions and a plurality of electrically isolated regions adjacent and interspersed with the electrically interconnected regions; and
a substantially transparent second layer comprising a dielectric film presenting a pair of opposing surfaces, wherein at least one of the opposing surfaces of the film is coated with a conductive material, the conductive material defining a plurality of electrically interconnected regions and a plurality of electrically isolated regions adjacent and interspersed with the electrically interconnected regions, the second layer superimposed on the first layer such that each of the electrically interconnected regions of the first layer is overlain with an electrically isolated region of the second layer, and each of the electrically isolated regions of the first layer is overlain with an electrically interconnected region of the second layer.

2. The touch screen of claim 1, wherein the conductive material of the first layer and the conductive material of the second layer substantially comprises indium tin oxide.

3. The touch screen of claim 1, wherein the dielectric film of the first layer and the dielectric film of the second layer substantially comprises polyethylene terephthalate or polyethylene naphthalate.

4. The touch screen of claim 1, wherein the electrically interconnected regions of the first layer are separated from the electrically isolated regions of the first layer by 100 μm or less.

5. The touch screen of claim 1, wherein the electrically interconnected regions of the first layer are separated from the electrically isolated regions of the first layer by 30 μm or less.

6. The touch screen of claim 1, wherein the electrically interconnected regions of the second layer are separated from the electrically isolated regions of the second layer by 100 μm or less.

7. The touch screen of claim 1, wherein the electrically interconnected regions of the second layer are separated from the electrically isolated regions of the second layer by 30 μm or less.

8. The touch screen of claim 1, wherein the electrically isolated regions of the first layer and the electrically isolated regions of the second layer are substantially square in shape.

9. A method of making a multilayer interdigitated projected capacitance touch screen comprising:
producing a first substantially transparent screen layer by using a directed energy beam ablation device to define a plurality of electrically interconnected regions and a plurality of electrically isolated regions adjacent and interspersed with the electrically interconnected regions in a conductive material coated on a dielectric material;
producing a second substantially transparent screen layer by using the directed energy beam ablation device to define a plurality of electrically interconnected regions and a plurality of electrically isolated regions adjacent and interspersed with the electrically interconnected regions in a conductive material coated on a dielectric material; and
superimposing the second layer on the first layer such that each of the electrically interconnected regions of the first layer is overlain with an electrically isolated region of the second layer, and each of the electrically isolated regions of the first layer is overlain with an electrically interconnected region of the second layer.

10. The method of claim 9, wherein the directed energy beam ablation device is a laser.

11. The method of claim 9, wherein the step of defining the plurality of electrically interconnected regions and the plurality of electrically isolated regions in the conductive material of the first layer is accomplished with one continuous pass of the directed energy beam ablation device.

12. The method of claim 9, wherein the step of defining the plurality of electrically interconnected regions and the plurality of electrically isolated regions in the conductive material of the second layer is accomplished with one continuous pass of the directed energy beam ablation device.

13. A capacitive touch screen comprising:
at least one substantially transparent layer comprising a dielectric film presenting a pair of opposing surfaces, wherein at least one of the opposing surfaces of the film is coated with a conductive material, the conductive material defining a plurality of electrically interconnected regions and a plurality of electrically isolated regions adjacent and interspersed with the electrically interconnected regions.

14. The touch screen of claim 13, wherein the conductive material substantially comprises indium tin oxide.

15. The touch screen of claim 13, wherein the dielectric film substantially comprises polyethylene terephthalate or polyethylene naphthalate.

16. The touch screen of claim 13, wherein the electrically interconnected regions are separated from the electrically isolated regions by 100 μm or less.

17. The touch screen of claim 13, wherein the electrically interconnected regions are separated from the electrically isolated regions by 30 μm or less.

18. The touch screen of claim 13, wherein the electrically isolated regions are substantially square in shape.
